(19) United States
(12) Patent Application Publication
(10) Pub. No.: US 2025/0350090 A1
(43) Pub. Date: Nov. 13, 2025

(54) HYBRID MEMBRANE EXTERNAL-CAVITY SURFACE EMITTING LASER

(71) Applicant: UNM RAINFOREST INNOVATIONS, Albuquerque, NM (US)

(72) Inventors: Mansoor SHEIK-BAHAE, Albuquerque, NM (US); Alexander Robert ALBRECHT, Albuquerque, NM (US); Mingyang ZHANG, Albuquerque, NM (US)

(21) Appl. No.: 19/277,571

(22) Filed: Jul. 23, 2025

Related U.S. Application Data
(63) Continuation of application No. 17/546,142, filed on Dec. 9, 2021.
(60) Provisional application No. 63/123,021, filed on Dec. 9, 2020.

(51) Int. Cl. H01S 5/024; H01S 5/028; H01S 5/04; H01S 5/14; H01S 5/183; H01S 5/343

(52) U.S. Cl. CPC H01S 5/02476; H01S 5/02469; H01S 5/028; H01S 5/041; H01S 5/14; H01S 5/18397; H01S 5/34313

(57) ABSTRACT

A hybrid membrane external-cavity surface-emitting laser is disclosed. The hybrid membrane external-cavity surface-emitting laser includes a semiconductor active gain structure comprising a top active gain surface and a bottom active gain surface; a first heat spreading structure comprising a top first heat spreading structure surface and a bottom first heat spreading structure surface, wherein the top first heat spreading structure surface is in thermal contact with the bottom active gain surface; and a reflecting structure comprising a top reflecting structure surface and a bottom reflecting structure surface, wherein the top reflecting structure surface is in contact with the bottom first heat spreading structure.

### CROSS-REFERENCE TO RELATED APPLICATIONS

This application is a continuation of U.S. patent application Ser. No. 17/546,142 filed on Dec. 9, 2021, which claims priority to U.S. Provisional patent application Ser. No. 63/123,021, filed Dec. 9, 2020, the disclosures of which are incorporated herein by reference in their entirety.

### GOVERNMENT RIGHTS

This invention was made with government support under Grant Nos FA9451-19-C-0504 and FA9550-16-1-0362 awarded by the U.S. Air Force Research Lab (AFRL). The government has certain rights in the invention.

### FIELD

This invention relates generally to external-cavity surface-emitting lasers, and specifically hybrid membrane external-cavity surface emitting lasers, a method of making the hybrid membrane external-cavity surface emitting lasers, and a method of using the hybrid membrane external-cavity surface emitting lasers.

### BACKGROUND

Optically pumped semiconductor lasers (OPSLs), also referred to as vertical-external-cavity surface-emitting lasers (VECSELs), or semiconductor disk lasers (SDLs), have rapidly established themselves as high-power, good beam quality sources for a variety of applications. Unlike other solid-state disk or fiber lasers, semiconductor lasers can be designed to operate over a large wavelength range, not easily accessible by other technologies. However, the output power of VECSELs has been limited to around 100 W, compared to several kW from fiber and disk lasers. The main limiting factor is thermal management. A VECSEL active mirror typically consist of a semiconductor active region—commonly multiple quantum wells (MQWs)—on top of a distributed Bragg reflector (DBR) inside an external cavity. FIG. 1 shows a conventional VECSEL arrangement 100. As shown in FIG. 1, the conventional VECSEL arrangement 100 comprises gain medium 105 composed of, for example, multiple quantum wells (MQW) in an alternating InGaAs/GaAs stack formed on top of a distributed Bragg reflector (DBR) 110. The DBR 110 is attached to a heat spreader 115, such as diamond, which is then attached to a heat sink 120. The VECSEL functions as one end of an optical cavity with a second reflector 125 at the other end. A laser beam from a pump laser 130, such as a diode laser operating at 810 nm and 70 W, is focused by lens 135 to the top surface of the VECSEL to provide the pumping of the VECSEL, The DBR 110 is formed by alternating layers of high and low index of refraction semiconductors, often in excess of 20 pairs and 5 microns in total thickness, to reach the required reflectivity values. This thickness and large number of material interfaces causes a high thermal resistance in the DBR, leading the active region to overheat, ultimately limiting the output power. Additional heat may also be generated in the DBR through absorption of pump laser not absorbed by the active region.

FIG. 2A, FIG. 2B, and FIG. 2C show a comparison of heat flow for DBR and DBR-free SDLs in a conventional VECSEL with DBR (FIG. 2A), a conventional single-heat-spreader membrane external-cavity surface emitting laser (MECSEL) (FIG. 2B), and a conventional dual-heat-spreader MECSEL (FIG. 2C). In the case of the VECSEL, heat must pass through the DBR before reaching the heat spreader, while in MECSELs the gain region is in direct contact with the heat spreader(s), improving heat sinking. The DBR-free SDLs remove the need for, and the thermal limitations of the DBR. Due to their transmission geometry (FIG. 2A-FIG. 2C), they rely on lateral heat transport in the heat spreader(s) (as shown by the heat flow lines), limiting their power scalability for some applications. Also, since the heat spreader is part of the laser cavity, it has to be of extremely high purity, to avoid excessive optical losses. SiC has been shown to achieve high performance devices. In comparison with the traditional DBR-based VECSEL gain chip (FIG. 2A), the concept of DBR-free gain chip is schematically shown in FIG. 2B and FIG. 2C for single and dual heat-spreaders, respectively. Such DBR-free lasers are now known in the international laser community as Membrane External-Cavity Surface-Emitting Laser or MECSELs.

Once gain modules are fabricated (FIG. 2A, FIG. 2B, FIG. 2C), MECSELs can be implemented in transmission geometry using typical cavity configurations shown in FIG. 3A and FIG. 3B. FIG. 3A and FIG. 3B shows conventional transmission geometry MECSEL cavities with single (FIG. 3A) and dual heat spreaders (FIG. 3B).

### SUMMARY

According to examples of the present disclosure, a hybrid membrane external-cavity surface-emitting laser is disclosed. The hybrid membrane external-cavity surface emitting laser comprises a semiconductor active gain structure comprising a top active gain surface and a bottom active gain surface; a first heat spreading structure comprising a top first heat spreading structure surface and a bottom first heat spreading structure surface, wherein the top first heat spreading structure surface is in thermal contact with the bottom active gain surface; and a reflecting structure comprising a top reflecting structure surface and a bottom reflecting structure surface, wherein the top reflecting structure surface is in contact with the bottom first heat spreading structure.

Various additional features can be included in the hybrid membrane external-cavity surface-emitting laser including one or more of the following features. The hybrid membrane external-cavity surface-emitting laser further comprises a second heat spreading structure comprising a top second heat spreading structure surface and a bottom second heat spreading structure surface, wherein the bottom second heat spreading structure surface is in thermal contact with the top active gain surface. The hybrid membrane external-cavity surface-emitting laser further comprises a heat sink structure in thermal contact with the first heat spreading structure and the reflecting structure. The hybrid membrane external-cavity surface-emitting laser further comprises an anti-reflective coating disposed on the top second heat spreading structure or disposed on the top active gain surface. The reflecting structure comprises a semiconductor distributed Bragg reflector, a dielectric stack, a metal, or combinations thereof. The first heat spreading structure, the second heat spreading structure, or both is about 0.1 to about 2.0 mm thick. The first heat spreading structure, the second heat spreading structure, or both is composed of SiC, sapphire, or diamond. The semiconductor active gain structure comprises multiple quantum wells. The semiconductor active gain structure comprises InGaAs/GaAs. The hybrid membrane external-cavity surface-emitting laser further comprises a pump laser configured to produce a pump laser beam incident on the top active gain surface. The hybrid membrane external-cavity surface-emitting laser further comprises a pump laser configured to produce a pump laser beam incident on the top second heat spreading structure. The hybrid membrane external-cavity surface-emitting laser further comprises a pump laser configured to produce a pump laser beam and one or more parabolic mirrors configured to reflect the pump laser and direct the pump laser beam to the semiconductor active gain structure.

According to example of the present disclosure, a method of forming a hybrid membrane external-cavity surface-emitting laser is disclosed. The method comprises forming a first heat spreading structure on a semiconductor active gain structure, wherein a top first heat spreading structure surface is in thermal contact with a bottom semiconductor active gain surface; thermally contacting a heat sink structure with the first heat spreading structure; and forming a reflecting structure on a bottom first heat spreading structure.

Various additional features can be included in the method of forming the hybrid membrane external-cavity surface-emitting laser including one or more of the following features. The method of forming a hybrid membrane external-cavity surface-emitting laser further comprises forming a second heat spreading structure on a top semiconductor active gain surface of the semiconductor active gain structure. The reflecting structure is formed by bonding to the bottom first heat spreading structure. The method of forming a hybrid membrane external-cavity surface-emitting laser further comprises forming an anti-reflective coating on a top second heat spreading structure. The reflecting structure comprises a semiconductor distributed Bragg reflector, a dielectric stack, a metal, or combinations thereof. The first heat spreading structure, the second heat spreading structure, or both is about 0.1 to about 2.0 mm thick. The first heat spreading structure, the second heat spreading structure, or both is composed of SiC, sapphire, or diamond. The semiconductor active gain structure comprises multiple quantum wells comprising InGaAs/GaAs.

According to examples of the present disclosure, a method of lasing from a hybrid membrane external-cavity surface-emitting laser is disclosed. The method comprises directing a pump laser beam from a pump laser to a hybrid membrane external-cavity surface-emitting laser to produce a probe laser beam from the hybrid membrane external-cavity surface-emitting laser, the hybrid membrane external-cavity surface-emitting laser comprising a semiconductor active gain structure comprising a top active gain surface and a bottom active gain surface; a first heat spreading structure comprising a top first heat spreading structure surface and a bottom first heat spreading structure surface, wherein the top first heat spreading structure surface is in thermal contact with the bottom active gain surface; and a reflecting structure comprising a top reflecting structure surface and a bottom reflecting structure surface, wherein the top reflecting structure surface is in contact with the bottom first heat spreading structure.

Advantages of the embodiments will be set forth in part in the description which follows, and in part will be understood from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE FIGURES

FIG. 1 shows a VECSEL arrangement.

FIG. 2A, FIG. 2B, and FIG. 2C show a comparison of heat flow for DBR and DBR-free SDLs in a conventional VECSEL with DBR (FIG. 2A), a conventional single-heat-spreader MECSEL (FIG. 2B), and a conventional dual-heat-spreader MECSEL (FIG. 2C).

FIG. 3A and FIG. 3B shows conventional transmission geometry MECSEL cavities with single (FIG. 3A) and dual heat spreaders (FIG. 3B).

FIG. 4 shows a H-MECSEL gain module according to examples of the present disclosure.

FIG. 5A and FIG. 5B shows a H-MECSEL and heat sink setup for (FIG. 5A) single and (FIG. 5B) dual heat spreader configurations, schematically showing the improved heat flow in the devices according to examples of the present disclosure, where thermal contact between heat spreader/mirror and heat sink can be improved by soldering or intermediate layers of soft, high thermal conductivity materials like heat sink compound or indium foil;

FIG. 6 shows a multi-pass pumping setup for H-MECSEL with dual-band/broadband reflector using a parabolic mirror (with hole at the center) and pair of flat mirrors to achieve multiple pump passes according to examples of the present disclosure;

FIG. 7A and FIG. 7B show a heat sink and cavity design for H-MECSEL with mirror designed to reflect the laser wavelength but transmit the pump wavelength, allowing for convenient, on-axis pumping through the back of the H-MECSEL gain module according to examples of the present disclosure;

FIG. 8 shows a plot of thermal modeling of various VECSEL geometries according to examples of the present disclosure; and

FIG. 9A, FIG. 9B, FIG. 9C, FIG. 9D, FIG. 9E, and FIG. 9F show the various VECSEL geometries of modeled in FIG. 8, where FIG. 9A shows a VECSEL with one heatspreader, FIG. 9B shows a MECSEL with one heatspreader, FIG. 9C shows a single bond H-MECSEL with one copper mount, FIG. 9D shows a single bond H-MECSEL with two copper mounts, FIG. 9E shows a MECSEL with two heatspreaders, and FIG. 9F shows a H-MECSEL with two heatspreaders.

### DETAILED DESCRIPTION

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

The following embodiments are described for illustrative purposes only with reference to the Figures. Those of skill in the art will appreciate that the following description is exemplary in nature, and that various modifications to the parameters set forth herein could be made without departing from the scope of the present invention. It is intended that the specification and examples be considered as examples only. The various embodiments are not necessarily mutually exclusive, as some embodiments can be combined with one or more other embodiments to form new embodiments.

Generally speaking, the present disclosure is related to a platform for improving the performance of membrane external-cavity surface emitting lasers (MECSELs). This platform is termed “Hybrid Membrane External-Cavity Surface-Emitting Laser (H-MECSEL). In the H-MECSEL gain module, the heat-spreader is mirrored (dielectric or metallic coating, by van der Waals bonding of an epi-grown semiconductor DBR), or a combination thereof. The mirrored section is then heat-sunk to facilitate vertical heat-transfer while also allowing for more efficient multipass pumping. The provides advantages over the conventional approaches by improving thermal management (leading to higher power), easing of laser implementation, and allow for multi-pass pumping.

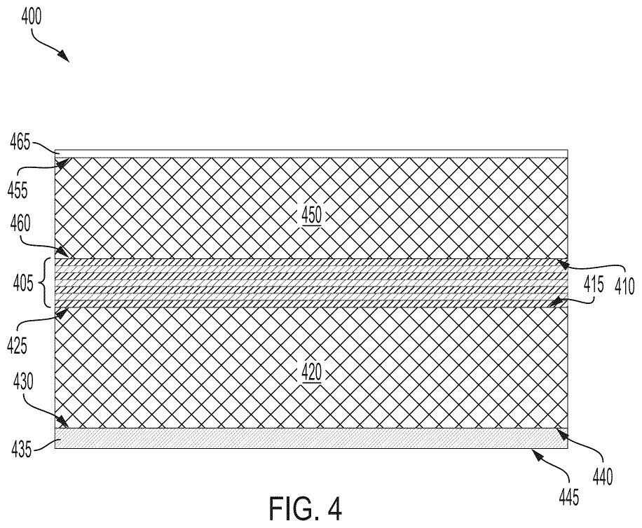

FIG. 4 show H-MECSEL 400 according to examples of the present disclosure. H-MECSEL 400 comprises gain structure 405, such as a semiconductor active gain structure. Gain structure comprises top active gain surface 410 and bottom active gain surface 415. In some examples, gain structure 405 comprises a semiconductor active gain structure comprising multiple quantum wells. In some examples, the semiconductor active gain structure comprises one or more quantum wells and/or one or more quantum well materials. In some examples, the semiconductor active gain structure comprises alternating layers of InGaAs/GaAs. In some examples, gain structure 405 can be composed of a bulk semiconductor material could be used. The material or material combination of gain structure 405 depends on the desired pump laser and H-MECSEL emission wavelengths. In some examples, gain structure 405 can have a thickness of about ˜2 μm.

In some examples, gain structure 405 can be formed as follows. The sample is grown on GaAs substrate. The sample comprises GaAs, with InGaAs quantum wells as the gain medium. For UV and visible applications, GaN/InGaN can be used. For red to near-IR, GaInP quantum wells, surrounded by AlGaInP on GaAs substrate can be used. For longer wavelengths in the IR, InP or GaSb substrates with various QW materials can be used.

H-MECSEL 400 further comprises first heat spreading structure 420. First heat spreading structure 420 comprises top first heat spreading structure surface 425 and bottom first heat spreading structure surface 430. Top first heat spreading structure surface is in thermal contact with bottom active gain surface 415.

H-MECSEL 400 further comprises reflecting structure 435. Reflecting structure 435 comprising top reflecting structure surface 440 and bottom reflecting structure surface 445. Top reflecting structure surface 440 is in contact with bottom first heat spreading structure 430. Reflecting structure 435 can comprise a semiconductor distributed Bragg reflector, a dielectric stack, a metal, or combinations thereof. Reflecting structure 35 can be a dual band reflecting structure (reflecting pump and laser wavelengths), single band reflecting structure (reflecting laser), or a reflecting laser structure with a high transmission at pump wavelength. In some examples, reflecting structure 435 can cover some or all of first heat spreading structure 420.

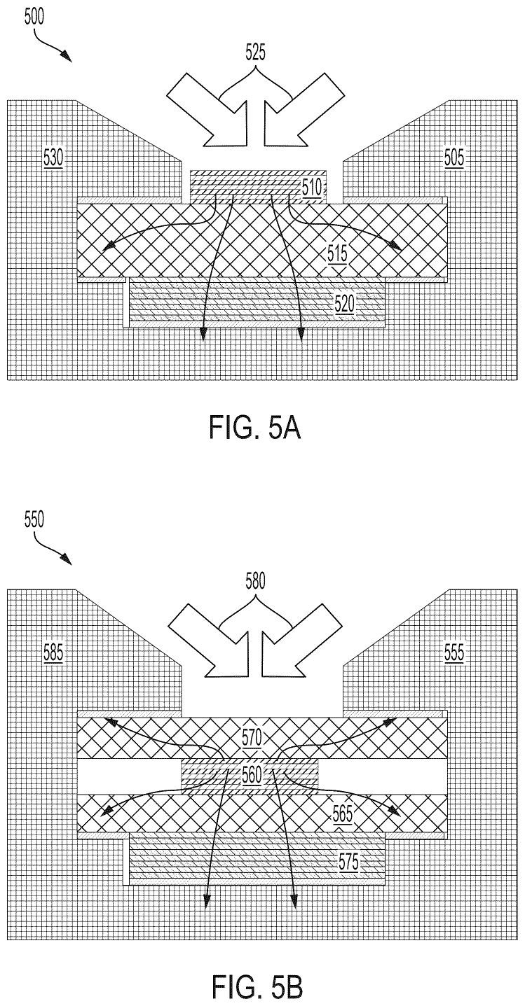

In some examples, reflecting structure 435 can be formed on bottom first heat spreading structure 430 as follows. For example, reflecting structure 435, such as a semiconductor DBR, can be formed on bottom first heat spreading structure 430 by bonding an epitaxially grown semiconductor DBR to first heat spreading structure 420. Since the main part of the heat flow from gain structure 405 to heat sink 505, 555 (as shown in FIG. 5A and FIG. 5B, respectively) does not pass through DBR 520, 575 (as shown in FIG. 5A and FIG. 5B, respectively), low thermal conductivity is no longer a significant issue. Also, in case reflecting structure 435 absorbs any of the transmitted pump light, that heat generated can directly be transferred to heat sink 505, 555, without significantly increasing gain structure 405 temperature. Alternately, reflecting structure 435, such as a dielectric mirror, can be directly coated onto bottom first heat spreading structure 420, which may have even lower thermal conductivity. However, this would not be a problem in this configuration. The dielectric coating would be less likely to absorb a significant amount of pump light either. In yet another alternative, for longer wavelength devices (mid-IR), reflecting structure 430 can be a metallic mirror coating, such as, but is not limited to, aluminum, silver, or gold. These would even have good thermal conductivity and may assist with cooling of bottom first heat spreading structure 420.

H-MECSEL 400 can further optionally comprise second heat spreading structure 450. Second heat spreading structure 450 comprises top second heat spreading structure surface 455 and bottom second heat spreading structure surface 460. Bottom second heat spreading structure surface 460 is in thermal contact with top active gain surface 410. In some examples, first heat spreading structure 420, second heat spreading structure 450, or both can be about 0.1 to about 2.0 mm thick. In some examples, first heat spreading structure 420, second heat spreading structure 450, or both is composed of SiC, sapphire, or diamond.

In some examples, first heat spreading structure 420 and second heat spreading structure 450 are composed of materials that have good optical quality (low absorption, low scattering, and high transparency at the laser and pump wavelengths), high thermal conductivity, mechanical/chemical stability and good surface quality (for bonding/adhesion). In the visible and near-IR, the most common material choices would be diamond (highest thermal conductivity), SiC (very good thermal conductivity, good optical quality, much cheaper than diamond), and Sapphire (lower thermal conductivity, very good surface and optical quality). Other materials can be used as well, e.g. Magnesium Fluoride. For longer wavelength operation, the materials can include, but are not limited to, GaAs, InP, or Si.

In some examples, the thickness of first heat spreading structure 420 and second heat spreading structure 450 can be somewhat flexible. For example, the thickness is thick enough to have enough mechanical stability for bonding and mounting. For example, a lower limit for the thickness can be about ˜0.1 mm. In terms of thermal performance, a thicker heat spreader is usually better However, if the absorption in the heat spreader is too high, it may impact performance. For example, a typical thickness can be between about 0.25-1 mm thickness. In some examples, if optical quality is good enough, or may be at longer wavelength, a larger thickness can be used. For example, an upper limit of the thickness can be about 10 mm.

H-MECSEL 400 can further optionally comprise heat sink structure 505, 555, as shown in FIG. 5A and FIG. 5B, respectively, in thermal contact with first heat spreading structure 420 and reflecting structure 435.

H-MECSEL 400 can further optionally comprise anti-reflective coating 465 disposed on top second heat spreading structure 455 or disposed on top active gain surface 410.

FIG. 5A and FIG. 5B shows a H-MECSEL and heat sink setup for single 500 (FIG. 5A) and dual 550 (FIG. 5B) heat spreader configurations, schematically showing the improved heat flow in the devices according to examples of the present disclosure. The thermal contact between heat spreader/mirror and heat sink can be improved by soldering or intermediate layers of soft, high thermal conductivity materials like heat sink compound or indium foil.

As shown in FIG. 5A and FIG. 5B, heat sink 505 and 555 are shown at least partially surrounding the H-MECSEL, respectively. In FIG. 5A, H-MECSEL comprises gain structure 510 (such as gain structure 405), heat spreader 515 (such as first heat spreading structure 420), and DBR 520 (such as reflecting structure 435). H-MECSEL is pumped by pump laser, as indicted by arrows 525. Heat produced by at least the pump laser is dissipated through heat spreader 515 to heat sink 505 as indicated by arrows 530. In FIG. 5B, H-MECSEL comprises gain structure 560 (such as gain structure 405), first heat spreader 565 (such as first heat spreading structure 420), second heat spreader 570 (such as second heat spreading structure 450), and DBR 575 (such as reflecting structure 435). H-MECSEL is pumped by pump laser, as indicted by arrows 580. Heat produced by at least the pump laser is dissipated through first heat spreader 565, second heat spreader 570, and DBR 575 to heat sink 555 as indicated by arrows 585.

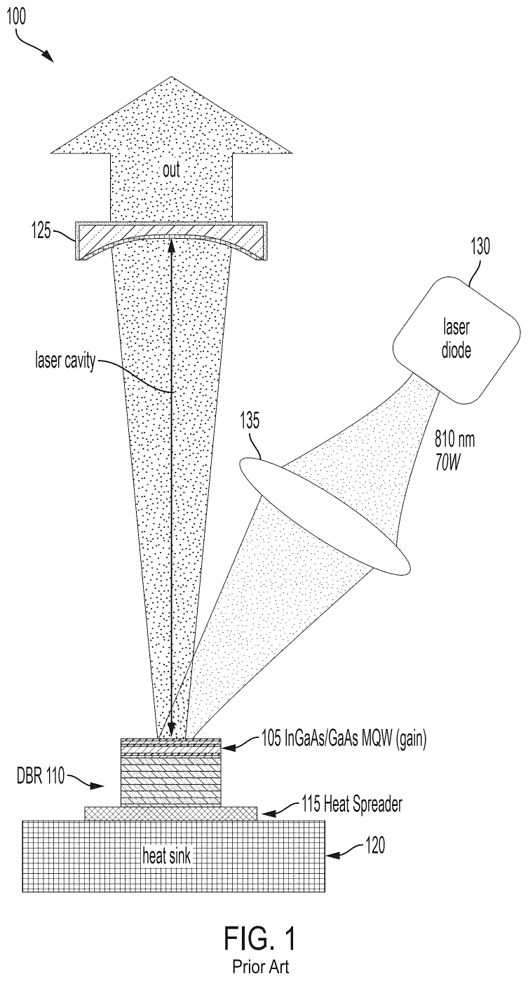

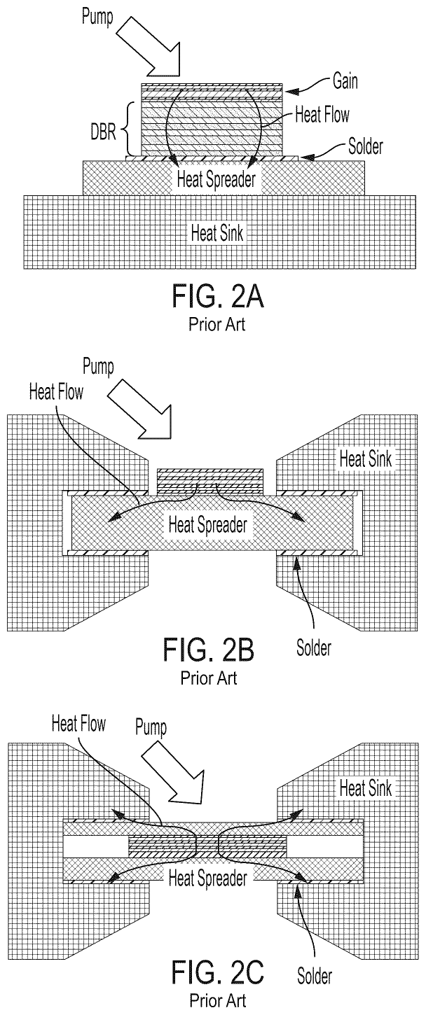

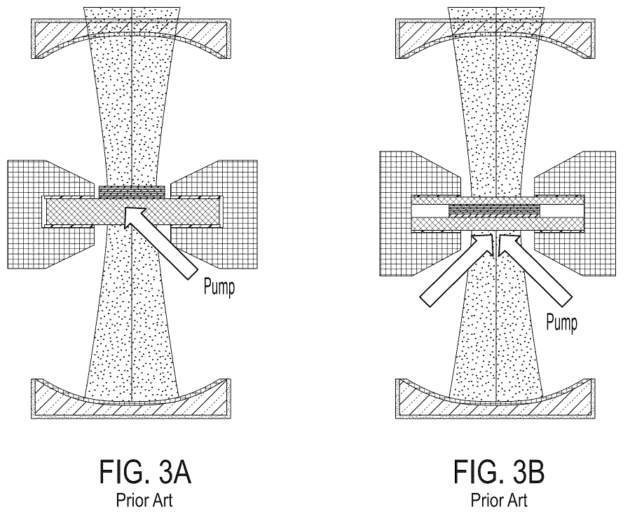

By attaching reflecting structure 435 to first heat spreading structure 420 on the opposite side of gain structure 405, the H-MECSEL can functions as a replacement for a regular VECSEL and can be used in a cavity design identical to the one shown in FIG. 1. For many applications this might be preferable over the transmission geometry (FIG. 3) as the number of external/adjustable optics is reduced, which results in a more robust and easier to align cavity. But since the heat spreader is still placed right next to the active region, it does not suffer from the thermal limitations of the VECSEL, especially when two heat spreaders are used.

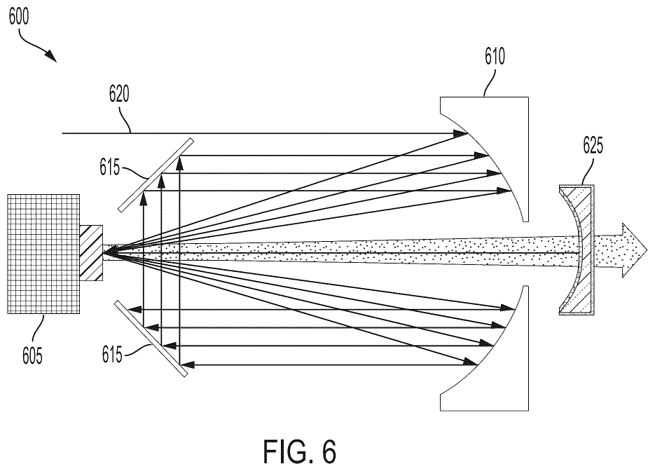

FIG. 6 shows a multi-pass pumping setup 600 for H-MECSEL 605, such as H-MECSEL 400, with dual-band/broadband reflector using a parabolic mirror 610 (with hole at the center) and pair of flat mirrors 615 to achieve multiple pump passes of pump beam 620 according to examples of the present disclosure. Optical coupler 625, such as a mirror, out-couples the light from H-MECSEL 605. In addition to the above-noted advantages, another application of the H-MECSEL is in multi-pass pumping, which is used when the pump absorption in the membrane is low. This could be due to a thin gain membrane, or more likely for in-well pumping, where the pump laser is absorbed in the quantum wells themselves, rather than the barrier layers in-between, which can further reduce the amount of heating in the membrane, and potentially lead to even higher output powers. The mirror of the H-MECSEL can be designed to reflect both the pump and laser wavelengths, either by having a broadband reflectivity, like is typically the case in metallic mirrors and some dielectric mirrors, or by specifically designing a dielectric mirror or DBR to fulfill both functions. This would automatically result in two passes of the pump through the membrane. If that is still not enough, an external multi-pass pumping system can be added, e.g. using a parabolic mirror (FIG. 6), like is common in standard disk lasers.

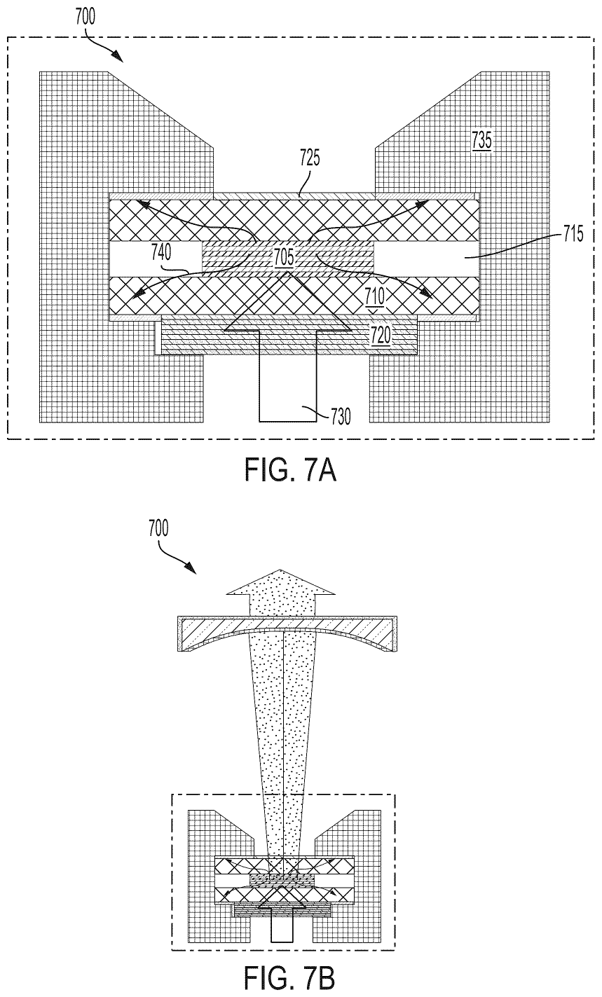

FIG. 7A and FIG. 7B show a heat sink and cavity design 700 for H-MECSEL with mirror designed to reflect the laser wavelength but transmit the pump wavelength, allowing for convenient, on-axis pumping through the back of the H-MECSEL gain module according to examples of the present disclosure. Instead of using a broadband mirror for both the pump and laser, a mirror is used that only reflects the laser, but transmits the pump. In this configuration and using a transmission-type heatsink, the H-MECSEL can be pumped from one side, while the laser cavity is on the other side. This can be advantageous when the best possible mode matching (beam area overlap) between the pump and laser mode is required, as this is the only practical scheme where the laser and pump beams are bother incident on the membrane normal to its surface.

As shown in FIG. 7A and FIG. 7B, H-MECSEL comprises gain structure 705 (such as gain structure 405), first heat spreader 710 (such as first heat spreading structure 420), second heat spreader 715 (such as second heat spreading structure 450), DBR 720 (such as reflecting structure 435), and anti-reflective coating 725. H-MECSEL is pumped by pump laser, as indicted by arrows 730. Heat produced by at least the pump laser is dissipated through first heat spreader 710 and second heat spreader 715 to heat sink 735 as indicated by arrows 740.

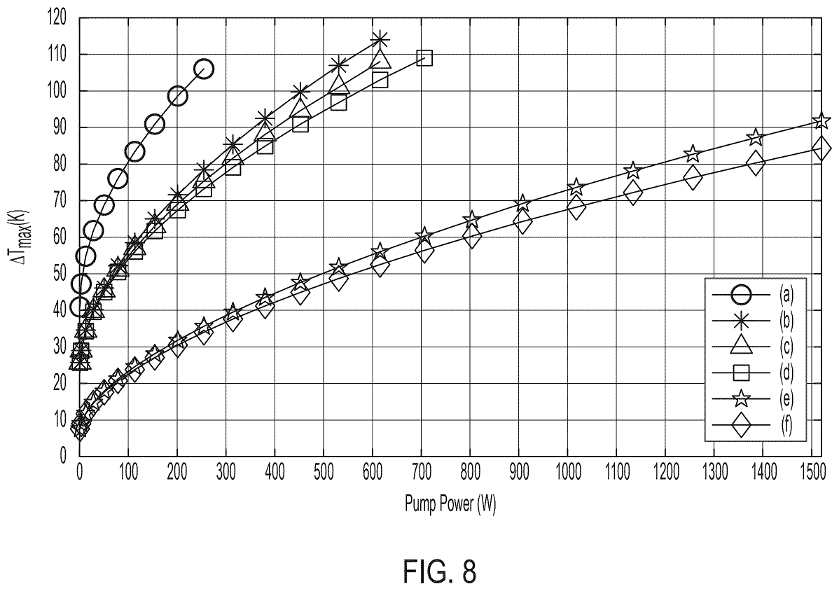

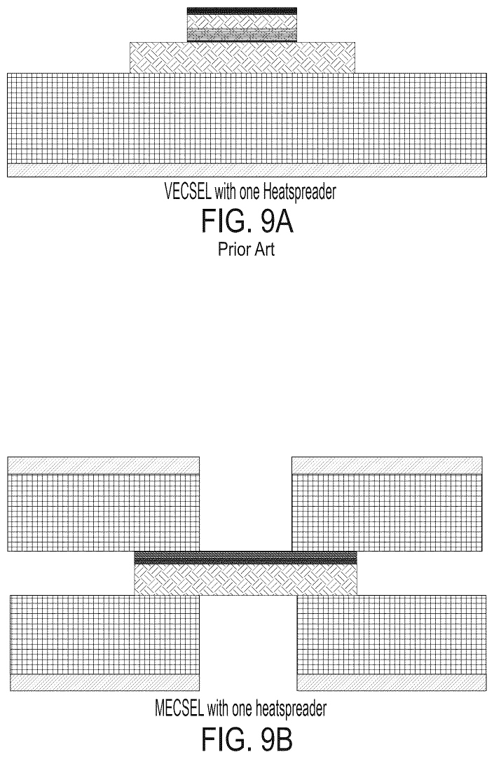

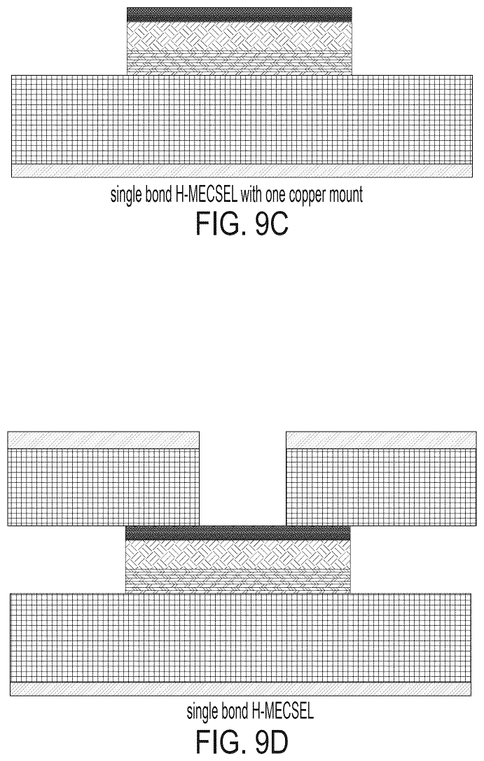

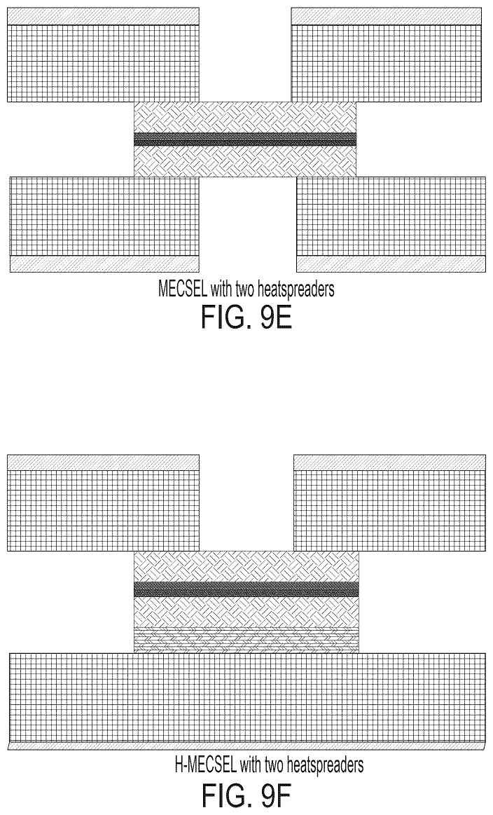

FIG. 8 shows a plot of thermal modelling of various VECSEL geometries, all using SiC heat spreaders according to examples of the present disclosure. Shown is the maximal temperature rise in the active region vs. pump power. Typically, a maximum temperature rise of about 100 K is acceptable for laser operation. Note that the temperature rise for all MECSEL geometries is lower than in a regular VECSEL (FIG. 9A), and that H-MECSEL is slightly lower than MECSEL, for the same heat spreader and heatsink configuration (e.g. FIG. 9F vs. FIG. 9G).

FIG. 9A, FIG. 9B, FIG. 9C, FIG. 9D, FIG. 9E, and FIG. 9F show the various VECSEL geometries of modeled in FIG. 8, where FIG. 9A shows a VECSEL with one heatspreader, FIG. 9B shows a single bond H-MECSEL, FIG. 9C shows a single bond H-MECSEL with one copper mount, FIG. 9D shows a MECSEL with one heatspreader, and FIG. 9E shows a VECSEL with two heatspreaders, FIG. 9F shows a MECSEL with two heatspreaders.

While the invention has been illustrated respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function.

Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “one or more of”, for example, A, B, and C means any of the following: either A, B, or C alone; or combinations of two, such as A and B, B and C, and A and C; or combinations of three A, B and C.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A laser system comprising:
a hybrid membrane vertical-external-cavity surface-emitting laser comprising:
an optically pumped semiconductor active gain structure that receives a pump laser beam;
a first heat spreading structure that is in thermal contact with a first region of the optically pumped semiconductor active gain surface;
a reflecting structure that is in contact with the first heat spreading structure; and
an external cavity reflector that is spaced apart from the optically pumped semiconductor active gain structure forming a free-space region between the external cavity reflector and the optically pumped semiconductor active gain structure.

2. The laser system of claim 1, further comprising one or more pump lasers configured to produce one or more pump laser beams incident on a bottom surface of the reflecting structure, wherein the reflecting structure is transmissive to the pump laser beam.

3. The laser system of claim 1, further comprising a pump laser configured to produce a pump laser beam incident on a top surface of the optically pumped semiconductor active gain structure.

4. The laser system of claim 1, wherein the reflecting structure is a semiconductor distributed Bragg reflector, a dielectric stack, a metal, or combinations thereof.

5. The laser system of claim 1, further comprising a first heat sink that is in thermal contact with a first region of the optically pumped semiconductor active gain structure.

6. The laser system of claim 5, further comprising a second heat sink that is in thermal contact with a second region of the optically pumped semiconductor active gain structure.

7. A method comprising:
forming a hybrid membrane vertical-external-cavity surface-emitting laser comprising:
forming a first heat spreading structure on an optically pumped semiconductor active gain structure, wherein the first heat spreading structure surface is in thermal contact with the optically pumped semiconductor active gain surface;
thermally contacting a heat sink structure with the first heat spreading structure;
forming a reflecting structure on the first heat spreading structure; and
forming an external cavity reflector that is spaced apart from the optically pumped semiconductor active gain structure forming a free-space region between the external cavity reflector and the optically pumped semiconductor active gain structure.

8. The method of claim 7, further comprising forming a second heat spreading structure on a top semiconductor active gain surface of the semiconductor active gain structure.

9. The method of claim 7, wherein the reflecting structure is formed by bonding to the bottom first heat spreading structure.

10. The method of claim 7, further comprising forming an anti-reflective coating on a top second heat spreading structure.

11. The method of claim 7, wherein the first heat spreading structure, the second heat spreading structure, or both is 0.1 to 2.0 mm thick.

12. The method of claim 7, wherein the first heat spreading structure, the second heat spreading structure, or both is composed of SiC, sapphire, or diamond.

13. A multi-pass laser pump system comprising:
a parabolic mirror with a central aperture configured to receive a pump laser beam from a pump laser;
a hybrid membrane vertical-external-cavity surface-emitting laser spaced apart from the parabolic mirror, the hybrid membrane vertical-external-cavity surface-emitting laser comprising:
an optically pumped semiconductor active gain structure that receives the pump laser beam;
a first heat spreading structure that is in thermal contact with the optically pumped semiconductor active gain surface;
a reflecting structure that is in contact with the first heat spreading structure; and
an external cavity reflector that is spaced apart from the optically pumped semiconductor active gain structure forming a free-space region between the external cavity reflector and the optically pumped semiconductor active gain structure,
wherein the pump laser beam is repeatedly reflected by the parabolic mirror and the hybrid membrane vertical-external-cavity surface-emitting laser to produce a probe laser beam that is directed through the central aperture of the parabolic mirror.

14. The multi-pass laser pump system claim 13, wherein the hybrid membrane vertical-external-cavity surface-emitting laser further comprises a second heat spreading structure comprising a top second heat spreading structure surface and a bottom second heat spreading structure surface, wherein the bottom second heat spreading structure surface is in thermal contact with the top active gain surface.

15. The multi-pass laser pump system claim 13, wherein the hybrid membrane vertical-external-cavity surface-emitting laser further comprises a heat sink structure in thermal contact with the first heat spreading structure and the reflecting structure.

16. The multi-pass laser pump system of claim 13, wherein the hybrid membrane vertical-external-cavity surface-emitting laser further comprises an anti-reflective coating disposed on the top second heat spreading structure or disposed on the top active gain surface.

17. The multi-pass laser pump system of claim 14, wherein the first heat spreading structure, the second heat spreading structure, or both is 0.1 to 2.0 mm thick.

18. The multi-pass laser pump system of claim 14, wherein the first heat spreading structure, the second heat spreading structure, or both is composed of SiC, sapphire, or diamond.

19. The multi-pass laser pump system of claim 13, wherein the semiconductor active gain structure comprises multiple quantum wells.

20. The multi-pass laser pump system of claim 13, wherein the semiconductor active gain structure comprises InGaAs/GaAs.
